(19) United States
(12) Patent Application Publication
(10) Pub. No.: US 2016/0181109 A1
(43) Pub. Date: Jun. 23, 2016

(54) SEMICONDUCTOR DEVICE MANUFACTURING METHOD

(71) Applicant: Tokyo Electron Limited, Tokyo (JP)

(72) Inventors: Yasushi Akasaka, Hsin-chu (TW); Koji Akiyama, Nirasaki-Shi (JP); Hirokazu Higashijima, Nirasaki-Shi (JP)

(21) Appl. No.: 15/054,663

(22) Filed: Feb. 26, 2016

Related U.S. Application Data
(62) Division of application No. 14/244,144, filed on Apr. 3, 2014.
Application No. 14/244,144 is a continuation of application No. PCT/JP2012/072646, filed on Sep. 5, 2012.

(30) Foreign Application Priority Data
Oct. 4, 2011 (JP) 2011-220257

(51) Int. Cl. H01L 21/28; H01L 21/8234; H01L 29/51; H01L 21/266; H01L 21/265; H01L 21/311

(52) U.S. Cl. CPC H01L 21/28229; H01L 21/26566; H01L 21/31111; H01L 29/517; H01L 21/266; H01L 21/823462

(57) ABSTRACT

A semiconductor device manufacturing method includes forming a dielectric film on a semiconductor substrate; forming a resist pattern on the dielectric film; irradiating an ionized gas cluster to a region of the dielectric film where the resist pattern is not formed; and removing a part of the region of the dielectric film in a thickness direction thereof where the ionized gas cluster is irradiated by a wet etching. The dielectric film serves as a gate insulating film, and two regions having different thicknesses of the dielectric film are formed.

### CROSS-REFERENCE TO RELATED APPLICATION

This Application is a Divisional Application of U.S. patent application Ser. No. 14/244,144, filed on Apr. 3, 2014, which is a Continuation of International Application No. PCT/JP2012/072646 filed on Sep. 5, 2012, which claims the benefit of Japanese Patent Application No. 2011-220257 filed on Oct. 4, 2011. The entire disclosure of the prior application is incorporated herein by reference in its entirety.

### TECHNICAL FIELD

The embodiments described herein pertain generally to a semiconductor device manufacturing method, and particularly, to a manufacturing method of a MISFET.

### BACKGROUND

Conventionally, a silicon oxide film has been used as a gate insulating film of a MIS (Metal-Insulator-Semiconductor)-type FET (Field-Effect Transistor). A silicon oxide film formed by thermally oxidizing a silicon substrate has fewer defects at an interface with respect to the silicon substrate and has a low risk of accidental dielectric breakdown, so that it can be an insulating film having a very high quality.

Recently, in response to demands for high integration of an advanced semiconductor device, a MISFET used in a LSI has been reduced in size while maintaining a proportional relationship, and has been continuously improved in performance. Currently, in the newest Logic LSI, a gate length is about 40 nm or less and a thickness of a silicon oxide film used as a gate insulating film is less than about 2 nm. According to the principle of a proportional scaling-down, desirably, a silicon oxide film having a thickness of about 1 nm may be used as a gate insulating film. However, in the silicon oxide film having a physical thickness of about 1 nm, a very high leakage current is generated due to direct tunneling to increase a power consumption of the LSI. In order to solve this problem, a film made of a metal oxide, for example, HfO₂, ZrO₂, Al₂O₃, TiO₂, or the like, which has a higher relative permittivity than a silicon oxide, (a so-called “high-k film”) has been used as a gate insulating film. Since the high-k film is used, even if a physical thickness of the film is great, a gate capacity equivalent to that of a silicon oxide can be obtained. Therefore, an increase in tunnel current can be suppressed, and a LSI having low power consumption can be manufactured.

Hereinafter, a semiconductor device manufacturing method according to a first conventional technology will be explained with reference to FIG. 1A to FIG. 1G.

Firstly, as depicted in FIG. 1A, a high-k film 12 is formed on a semiconductor substrate 11 such as a Si substrate by using a CVD (Chemical Vapor Deposition) method or an ALD (Atomic Layer Deposition) method. A representative example of the high-k film 12 formed herein is a film mainly made of HfO₂ (hafnium oxide).

Then, as depicted in FIG. 1B, an electrode film 13 is formed on the high-k film 12. The electrode film 13 may be formed in a single layer of polycrystalline silicon or may have a stacked structure in which a metal layer, such as TiN, is formed as a lower layer and polycrystalline silicon is formed as an upper layer thereon.

Thereafter, as depicted in FIG. 1C, a hard mask layer 14 is formed, and a resist pattern 15 is formed thereon by a photolithography method or the like. Then, a region where the hard mask layer 14 is exposed with the resist pattern 15 serving as a mask is removed by anisotropic etching such as RIE (Reactive Ion Etching) or the like. Then, the resist pattern 15 is removed by ashing or the like, so that a hard mask 14a is formed as depicted in FIG. 1D.

Then, as depicted in FIG. 1E, a region where the electrode film 13 is exposed with the hard mask 14a serving as a mask is selectively etched with respect to the high-k film 12, so that a gate electrode 13a is formed.

Thereafter, as depicted in FIG. 1F, anisotropic etching such as RIE or the like is carried out with the hard mask 14a and the gate electrode 13a serving as masks, so that the exposed high-k film 12 is selectively etched with respect to the semiconductor substrate 11, and the semiconductor substrate 11 is exposed. Thus, a high-k film 12a of a gate region is formed.

Then, by a combined process of low-acceleration ion implantation, high-temperature short-time annealing, and the like, source/drain containing a thin impurity diffusion layer, and a wiring are formed, so that a MISFET including a high-k gate insulating film can be formed.

Further, when the high-k film 12 at the region where the gate electrode 13a is not formed is removed by isotropic etching such as wet etching instead of the anisotropic etching, a same effect can be obtained. FIG. 1G shows a cross sectional view of a typical semiconductor device manufactured according to such a method.

Meanwhile, when a LSI is actually manufactured, FETs having different specifications in the same chip in response to circuit requirements have been typically used. In this case, gate insulating films of the FETs may have different thicknesses according to the specifications such as a leakage current or a breakdown voltage of an insulating film. Hereinafter, a semiconductor device manufacturing method according to a second conventional technology will be explained with reference to FIG. 2A to FIG. 2F. This method relates to a method of forming gate insulating films having various thicknesses by using high-k.

Firstly, as depicted in FIG. 2A, an element isolation region 22 and a well 23 are formed in a semiconductor substrate 21 such as a Si substrate. Further, a surface of the semiconductor substrate 21 is thermally oxidized, so that a SiO₂ film 24 is formed.

Then, as depicted in FIG. 2B, a resist pattern 25 is formed by a photolithography method or the like.

Thereafter, as depicted in FIG. 2C, the SiO₂ film 24 at a region where the resist pattern 25 is not formed is removed by using dilute hydrofluoric acid or the like.

Then, as depicted in FIG. 2D, the resist pattern 25 is removed by ashing or using a mixed liquid of H₂SO₄ and H₂O₂. Thus, there are formed a region a1 where the SiO₂ film 24 is formed and a region a2 where the SiO₂ film 24 is not formed.

Thereafter, as depicted in FIG. 2E, a SiO₂ film is formed on the surface of the semiconductor substrate 21 by thermal oxidation. Thus, at the region a1 where the SiO₂ film 24 is formed, a SiO₂ film 26a including the SiO₂ film 24 and having a larger thickness is formed, and at the region a2 where the SiO₂ film 24 is not formed, a SiO₂ film 26b formed by the thermal oxidation and having a smaller thickness is formed.

Then, as depicted in FIG. 2F, a high-k film 27 is formed. Thus, at the region a1, an insulating film in which the thick SiO₂ film 26a and the high-k film 27 are stacked is formed, and at the region a2, an insulting film in which the thin SiO₂ film 26b and the high-k film 27 are stacked is formed.

Thereafter, a gate electrode and source/drain are formed in the same manner as the first conventional example, so that a MISFET is manufactured.

Although there has been explained the manufacturing method of the MISFET including the two insulating films having different thicknesses, it is possible to manufacture a MISFET including more than two insulating films having different thicknesses by performing photolithography, wet etching, and oxidation a desired number of times.

Patent Document 1: Japanese Patent Laid-open Publication No. 2004-071973

Patent Document 2: Japanese Patent Laid-open Publication No. 2002-033477

However, according to the semiconductor device manufacturing method of the first conventional technology, in the etching process, such as RIE or the like, depicted in FIG. 1F, even if attention is paid to selectivity with respect to the semiconductor substrate, the selectivity is not sufficient in most cases, so that overetching 16a occurs at the semiconductor substrate 11 such as a Si substrate. Further, since etching is performed with ions having kinetic energy in a direction perpendicular to a substrate surface of the semiconductor substrate 11, damage 16b easily occurs at an etched portion of the semiconductor substrate 11. Therefore, performance of a semiconductor device to be manufactured can be deteriorated.

Further, according to the semiconductor device manufacturing method of the second conventional technology, as depicted in FIG. 2C, the resist pattern 25 is formed on a surface of the SiO₂ film 24, and the SiO₂ film 24 at the region where the resist pattern 25 is not formed is removed by RIE or the like. Therefore, C (carbon) or the like contained in the resist pattern or an etching gas is attached and diffused to a surface of the semiconductor substrate 21 or the SiO₂ film 24. As a result, an interface state is generated at an interface between the semiconductor substrate 21 and the gate insulating film or a dielectric breakdown voltage of the gate insulating film is reduced.

Therefore, there have been demanded a semiconductor device manufacturing method capable of forming a gate insulating film by completely removing a dielectric film without damage to a substrate, and a semiconductor device manufacturing method capable of forming dielectric films having different thicknesses on a substrate such as a silicon substrate while maintaining a clean surface of the substrate.

### SUMMARY

In an example embodiment, a semiconductor device manufacturing method includes forming a dielectric film on a semiconductor substrate; performing a heat treatment on the dielectric film; forming an electrode on a first region of the dielectric film; irradiating an ionized gas cluster to a second region of the dielectric film where the electrode is not formed; and removing the second region of the dielectric film where the ionized gas cluster is irradiated by a wet etching after the irradiating of the ionized gas cluster.

In another example embodiment, a semiconductor device manufacturing method includes forming a dielectric film on a semiconductor substrate; forming a resist pattern on the dielectric film; irradiating an ionized gas cluster to a region of the dielectric film where the resist pattern is not formed; and removing a part of the region of the dielectric film in a thickness direction thereof where the ionized gas cluster is irradiated by a wet etching. Further, the dielectric film serves as a gate insulating film, and two regions having different thicknesses of the dielectric film are formed.

In still another example embodiment, a semiconductor device manufacturing method includes forming a first dielectric film on a semiconductor substrate; forming a second dielectric film, which is made of a material having a relative permittivity higher than a relative permittivity of a material forming the first dielectric film, on the first dielectric film; forming a resist pattern on the second dielectric film; irradiating an ionized gas cluster to a region of the second dielectric film where the resist pattern is not formed; and removing a part of the region of the second dielectric film in a thickness direction thereof where the ionized gas cluster is irradiated by a wet etching. Further, a gate insulating film is formed of the first dielectric film and the second dielectric film, and the gate insulating film has different thicknesses at the region where the ionized gas cluster is irradiated and a region where the ionized gas cluster is not irradiated.

In accordance with the example embodiments, it is possible to provide a semiconductor device manufacturing method in which a high-k film can completely removed without damage to a substrate when the high-k film is used as a gate insulating film, and a semiconductor device manufacturing method in which introduction of contaminants can be suppressed as far as possible when high-k films having different thicknesses are formed on a substrate.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent from the following detailed description. The use of the same reference numbers in different figures indicates similar or identical items.

FIG. 1A is a cross sectional view illustrating a first process of a semiconductor device manufacturing method in accordance with a first conventional technology;

FIG. 1B is a cross sectional view illustrating a second process of the semiconductor device manufacturing method in accordance with the first conventional technology;

FIG. 1C is a cross sectional view illustrating a third process of the semiconductor device manufacturing method in accordance with the first conventional technology;

FIG. 1D is a cross sectional view illustrating a fourth process of the semiconductor device manufacturing method in accordance with the first conventional technology;

FIG. 1E is a cross sectional view illustrating a fifth process of the semiconductor device manufacturing method in accordance with the first conventional technology;

FIG. 1F is a cross sectional view illustrating a sixth process of the semiconductor device manufacturing method in accordance with the first conventional technology;

FIG. 1G is an explanatory diagram illustrating another semiconductor device manufacturing method in accordance with the first conventional technology;

FIG. 2A is a cross sectional view illustrating a first process of a semiconductor device manufacturing method in accordance with a second conventional technology;

FIG. 2B is a cross sectional view illustrating a second process of the semiconductor device manufacturing method in accordance with the second conventional technology;

FIG. 2C is a cross sectional view illustrating a third process of the semiconductor device manufacturing method in accordance with the second conventional technology;

FIG. 2D is a cross sectional view illustrating a fourth process of the semiconductor device manufacturing method in accordance with the second conventional technology;

FIG. 2E is a cross sectional view illustrating a fifth process of the semiconductor device manufacturing method in accordance with the second conventional technology;

FIG. 2F is a cross sectional view illustrating a sixth process of the semiconductor device manufacturing method in accordance with the second conventional technology;

FIG. 3A is a cross sectional view illustrating a first process of a semiconductor device manufacturing method in accordance with a first example embodiment;

FIG. 3B is a cross sectional view illustrating a second process of the semiconductor device manufacturing method in accordance with the first example embodiment;

FIG. 3C is a cross sectional view illustrating a third process of the semiconductor device manufacturing method in accordance with the first example embodiment;

FIG. 3D is a cross sectional view illustrating a fourth process of the semiconductor device manufacturing method in accordance with the first example embodiment;

FIG. 3E is a cross sectional view illustrating a fifth process of the semiconductor device manufacturing method in accordance with the first example embodiment;

FIG. 3F is a cross sectional view illustrating a sixth process of the semiconductor device manufacturing method in accordance with the first example embodiment;

FIG. 3G is a cross sectional view illustrating a seventh process of the semiconductor device manufacturing method in accordance with the first example embodiment;

FIG. 4 is a characteristic graph of a high-k film depending on whether a gas cluster is irradiated or not;

FIG. 5 is a configuration view of a gas cluster irradiation device;

FIG. 6A is a cross sectional view illustrating a first process of a semiconductor device manufacturing method in accordance with a second example embodiment;

FIG. 6B is a cross sectional view illustrating a second process of the semiconductor device manufacturing method in accordance with the second example embodiment;

FIG. 6C is a cross sectional view illustrating a third process of the semiconductor device manufacturing method in accordance with the second example embodiment;

FIG. 6D is a cross sectional view illustrating a fourth process of the semiconductor device manufacturing method in accordance with the second example embodiment; and

FIG. 6E is a cross sectional view illustrating a fifth process of the semiconductor device manufacturing method in accordance with the second example embodiment.

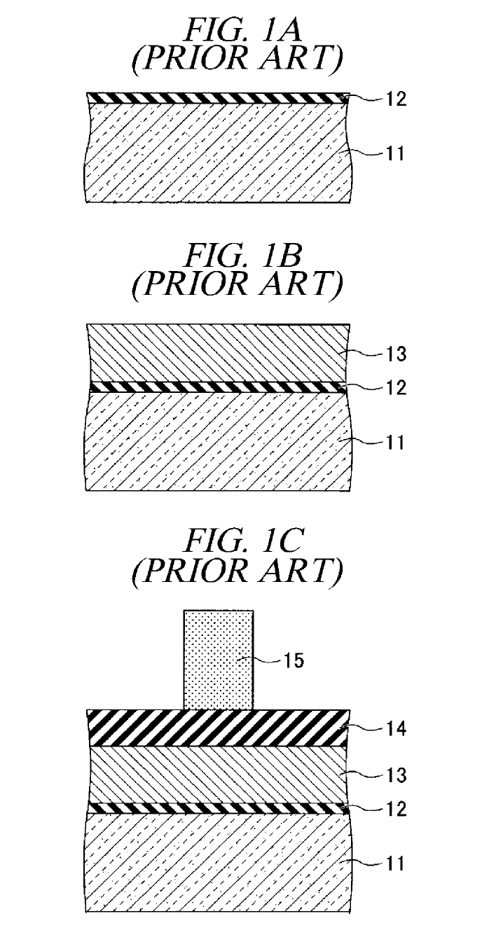

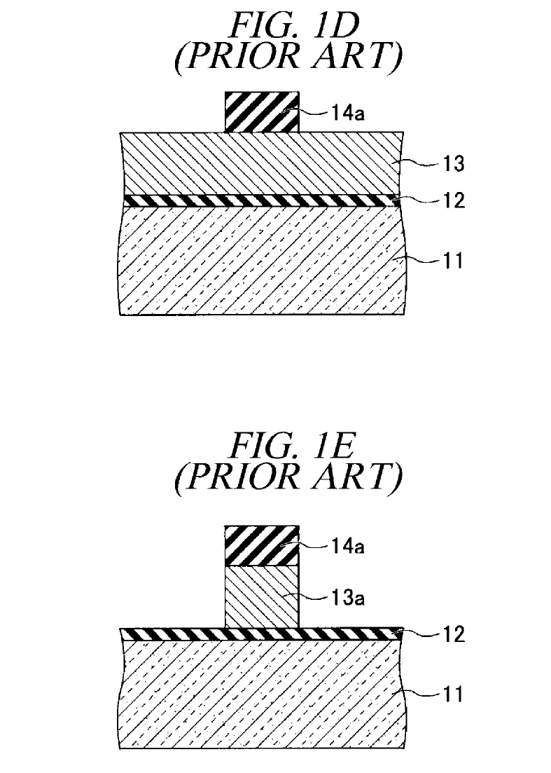

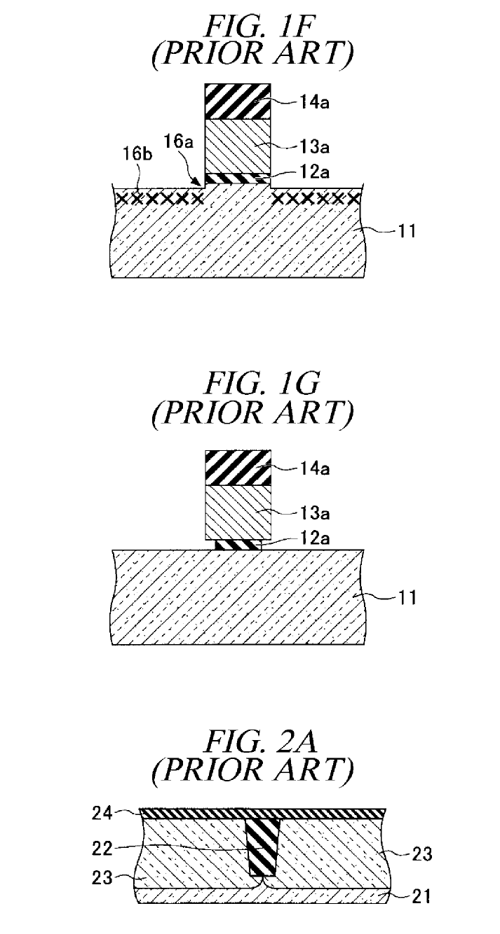

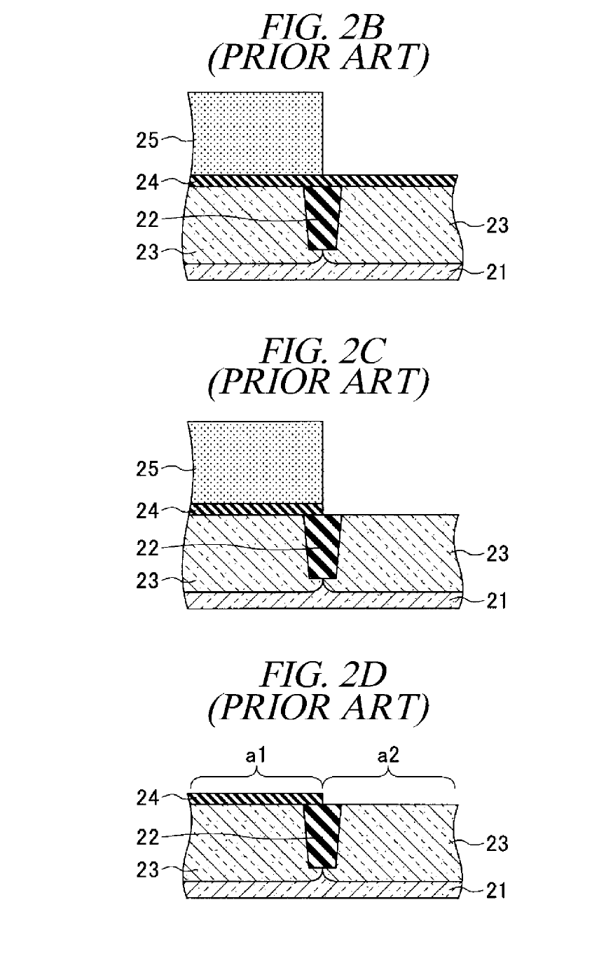

### EXPLANATION OF REFERENCE NUMERALS

11: Semiconductor substrate
12: High-k film
12a: High-k film of gate region
13: Electrode film
13a: Gate electrode
14: Hard mask layer
14a: Hard mask
15: Resist pattern
21: Semiconductor substrate
22: Element isolation region
23: Well
24: SiO₂ film
25: Resist pattern
26: SiO₂ film
27: High-k film
51: Nozzle unit
52: Ionization electrode
53: Acceleration electrode
54: Cluster separating unit
55: Gas cluster
101: Semiconductor substrate
102: High-k film
102a: High-k film of gate region
102b: Modified layer
103: Electrode film
103a: Gate electrode
104: Hard mask layer
104a: Hard mask
105: Resist pattern
201: Semiconductor substrate
202: Element isolation region
203: Well
204: Interface layer
205: High-k film
205a: Modified layer
205b: Thick high-k film
205c: Thin high-k film
206: Resist pattern
207: Gas cluster
b1: Region where thick high-k film is formed
b2: Region where thin high-k film is formed

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current example. Still, the examples described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, example embodiments will be explained with reference to the accompanying drawings.

### First Example Embodiment

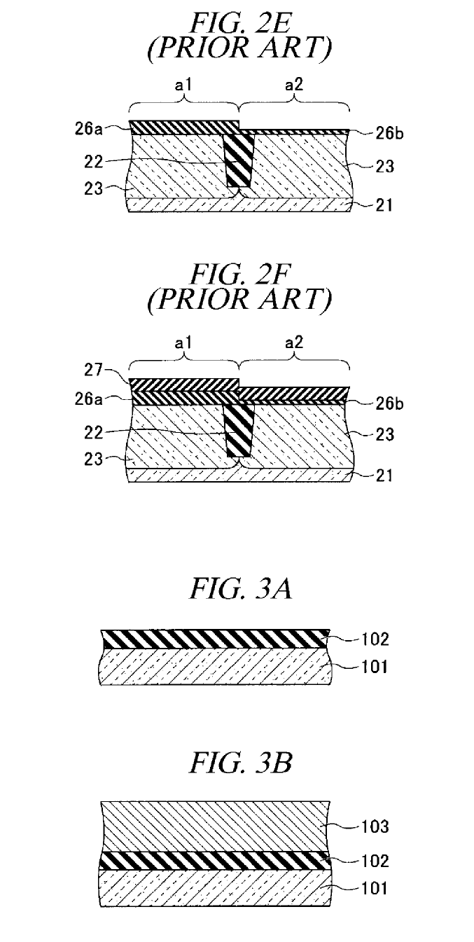

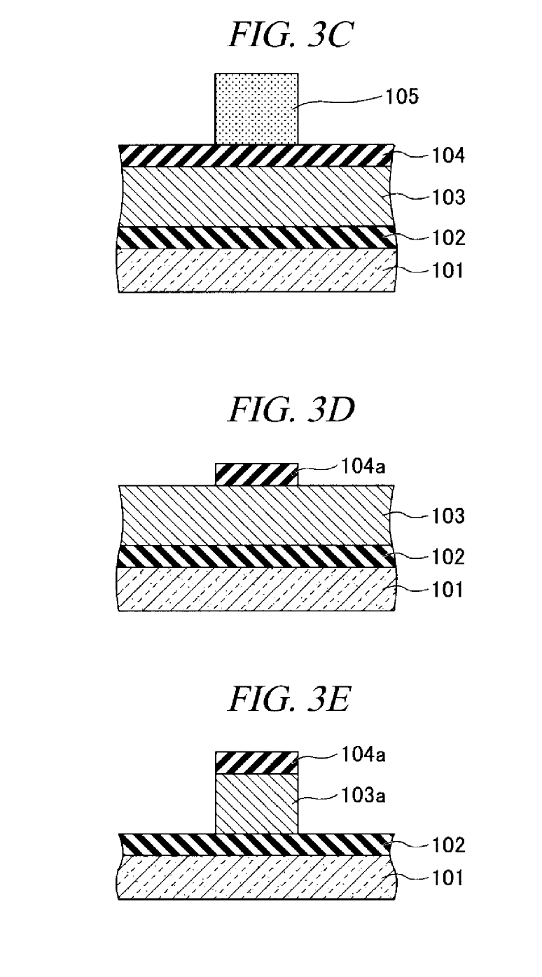

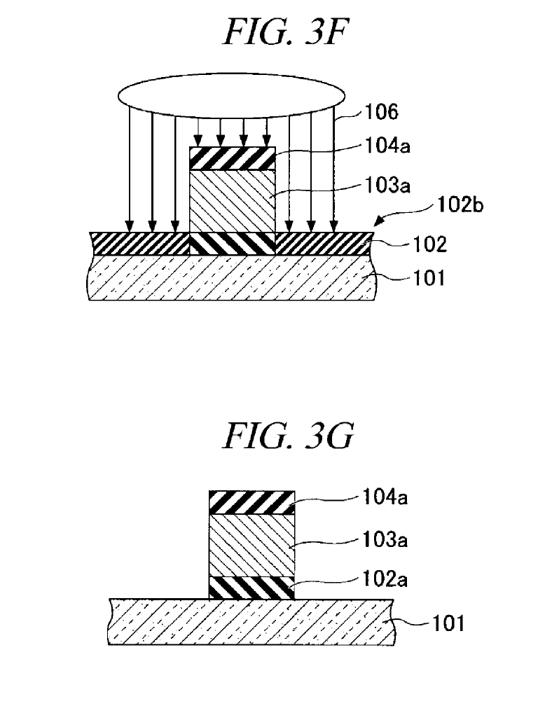

A first example embodiment will be explained with reference to FIG. 3A to FIG. 3G. The present example embodiment relates to a semiconductor device manufacturing method forming a high-k film as a gate insulating film.

Firstly, as depicted in FIG. 3A, a high-k film 102 is formed on a semiconductor substrate 101 such as a Si substrate. As a material of the high-k film 102 formed herein, HfO₂ (hafnium oxide), ZrO₂ (zirconium oxide), Al₂O₃ (aluminum oxide), Ta₂O₅ (tantalum pentoxide), TiO₂ (titanium oxide), rare earth oxides and mixtures thereof, materials in which Si is added thereto, and materials in which a nitriding process is performed thereon may be used. Although CVD or ALD may be performed in forming a high-k film, PVD or a plasma nitriding process may be performed together depending on a kind of a material to be added. A thickness of the high-k film 102, which is currently used in the newest Logic LSI, is typically less than about 2 nm. After the high-k film 102 is formed, a heat treatment is carried out at about 500° C. to about 800° C. for several minutes to several ten minutes, or at about 900° C. to about 1100° C. for several seconds, desirably. As an atmosphere for carrying out the heat treatment, an atmosphere of an inert gas such as Ar, N₂, or the like, or the inert gas with addition of oxygen in a very small amount of several % or less may be suitable. This heat treatment has an effect of densifying the high-k film and increasing a relative permittivity and also has an effect of reducing an etching rate with dilute hydrofluoric acid as described below.

Then, as depicted in FIG. 3B, an electrode film 103 is formed on the high-k film 102. A representative example of the electrode film 103 may be polycrystalline silicon or the like. In order to reduce a resistance and provide a work function to the polycrystalline silicon as an electrode, the polycrystalline silicon is added with n-type conductive impurities such as As (arsenic), P (phosphorous), and the like, or p-type conductive impurities such as B (boron) and the like, and then, a heat treatment is carried out to electrically activate the polycrystalline silicon. The addition of impurities and activation may be carried out before a gate electrode is patterned or after the gate electrode is patterned and a mask is removed. Further, as the gate electrode, there may be used a layered structure in which a metal having a desired work function is deposited as a lower layer and a film configured to reduce a sheet resistance of the electrode, e.g., a film containing polycrystalline silicon with addition of conductive impurities or a film containing W is appropriately stacked thereon. These films need to have a sufficiently low etching rate with respect to dilute hydrofluoric acid in removing a part of the high-k film 102 with the dilute hydrofluoric acid.

Thereafter, as depicted in FIG. 3C, a SiO₂ film as a hard mask layer 104 is formed on the electrode film 103, and a resist pattern 105 is formed on the hard mask layer 104. Although SiO₂ is typically used as a main component of the hard mask layer, SiN or the like may be appropriately selected as the main component depending on a material of the electrode film 103. Further, the resist pattern 105 is formed at a region where a hard mask 104a to be described below is formed on the hard mask layer 104 by coating photoresist on the hard mask layer 104 and performing pre-baking and exposure/development with an exposure device.

Then, as depicted in FIG. 3D, the hard mask layer 104 is anisotropically etched with the resist pattern 105 serving as a mask, and then, the resist pattern 105 is removed by ashing or the like. Thus, the hard mask 104a is formed.

Thereafter, as depicted in FIG. 3E, the exposed electrode film 103 is removed by performing the anisotropic etching with the hard mask 104a serving as a mask, so that a gate electrode 103a is formed. In this case, it is known that the polycrystalline silicon, metal, and the like as materials of the electrode film 103 can be etched well by performing the anisotropic etching such as RIE or the like with a gas containing HBr, Cl₂, SF₆, NF₃, or the like. Meanwhile, typically, it is known that in the etching process without heating the substrate with these gases, an etching rate of the high-k film 102 is very low. For this reason, the high-k film 102 remains as depicted in the drawing.

Then, as depicted in FIG. 3F, the high-k film 102 at a region where the gate electrode 103a is not formed is modified by irradiating an ionized gas cluster 106, so that a modified film 102b is formed. The modified film 102b has a high etching rate with respect to a liquid containing hydrofluoric acid as described below. Further, an ionized gas cluster irradiation device will be explained below. Examples of an element used for an ionized gas cluster may include argon, oxygen, nitrogen, and the like.

Thereafter, as depicted in FIG. 3G, by using the liquid containing hydrofluoric acid, the modified film 102b is removed. Thus, the high-k film 102a of a gate region can be formed only at the region where the gate electrode 103a is formed.

Then, ions are implanted into the semiconductor substrate 101 with the hard mask 104a and the gate electrode 103a serving as masks, so that source/drain electrodes are self-aligned with respect to the gate electrode 103a, and then, an interlayer insulating film and a wiring are formed by a well-known method. Thus, a MISFET including a high-k film can be formed (not illustrated).

According to the semiconductor device manufacturing method in accordance with the present example embodiment, the high-k film 102 at a region where a surface of the high-k film 102 is exposed becomes the modified film 102b and can be completely removed by wet etching without damage to the semiconductor substrate 101. Thus, it is possible to manufacture a high-quality MISFET having a low junction leakage current of the source/drain to be formed later.

(Characteristics of High-k Film)

Hereinafter, etching characteristics of the high-k film formed in accordance with the present example embodiment will be explained. A material of the high-k film used herein is aluminum oxide, and the high-k film is formed by using a CVD method. Further, a sample A is obtained by forming a high-k film to about 20 nm and performing a heat treatment thereto at about 850° C. for about 300 seconds. A sample B is obtained by performing the same heat treatment as the sample A and irradiating a cluster ion.

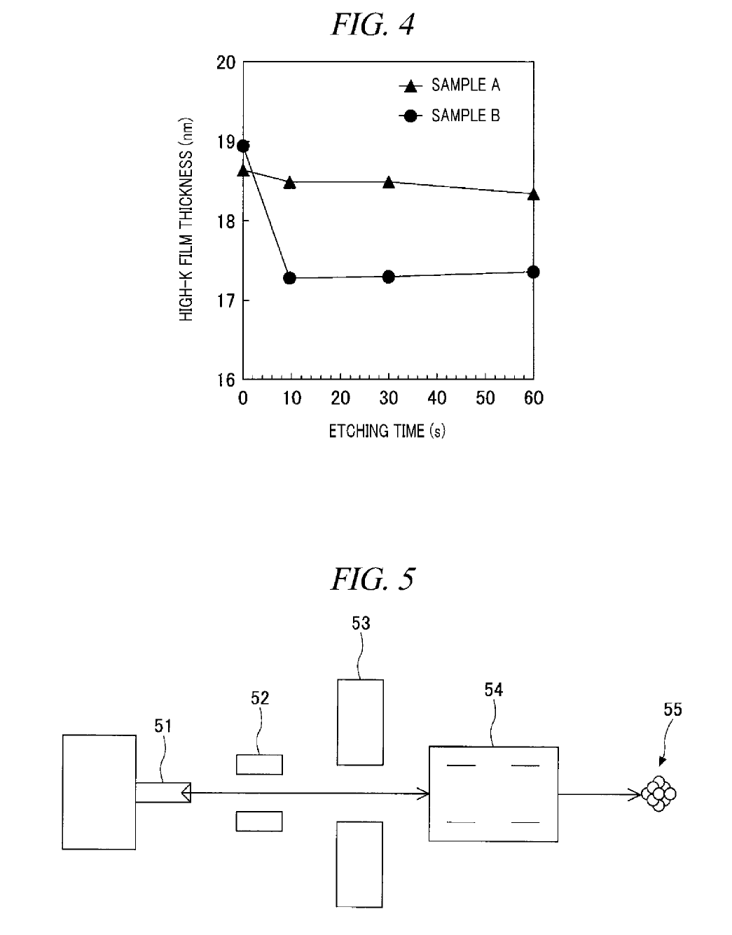

FIG. 4 shows a dependency of a thickness of a high-k film on a time when performing the wet etching with a liquid containing pure water and hydrofluoric acid at a ratio of 1:100. As for the sample A, since the high-k film is crystallized by the heat treatment, it is rarely etched with dilute hydrofluoric acid. Meanwhile, as for the sample B, a surface of the high-k film is etched to about 1 nm to about 2 nm with dilute hydrofluoric acid but rarely further etched.

As such, by irradiating an ionized gas cluster to a surface, a state of the surface is modified. Therefore, as depicted in FIG. 3F that explains the present example embodiment, it is assumed that the high-k film can be easily etched with the dilute hydrofluoric acid since a surface of the high-k film at a region where an ionized gas cluster is irradiated is modified to about 1 nm to about 2 nm.

Further, in the example embodiment, a thickness of the modified high-k film can be adjusted by controlling a condition of the ionized gas cluster.

Furthermore, the above-described characteristics of the high-k film are explained by using Al₂O₃, but HfO₂, ZrO₂, Ta₂O₅, and TiO₂ have the same tendency.

Moreover, in the present example embodiment, a gas cluster of ionized oxygen is used as the ionized gas cluster, but even in the case of using a gas cluster of ionized nitrogen and argon, the same effect can be obtained.

Further, a representative example of a method of introducing elements into a film is an ion implantation method. However, in a method of implanting ions of ionized atoms or molecules into a film, it is very difficult to modify (reform) a thin high-k film only and the ions may penetrate the high-k film to affect the substrate.

Furthermore, in order to modify the film, it is necessary to implant atoms having a density of about 1×10²¹ to about 1×10²² cm⁻³. However, if a density of atoms implanted into the Si substrate in contact with the film exceeds about 1×10¹⁸ cm⁻³, there are problems such as oxidation of the Si substrate. Accordingly, by using the ion implantation, it is very difficult to obtain a profile satisfying both requirements of modifying the film and of not oxidizing the Si substrate. Further, if ions are implanted into the crystallized film as described in the present example embodiment, there occurs a phenomenon called “channeling” in which some ions do not be scattered but passed through in a specific crystal orientation. Therefore, ions are more likely to reach a deep position of the film.

Meanwhile, by using the gas cluster implantation, it is possible to obtain a profile satisfying such requirements since a principle of ion implantation is different from a principle of impurity introduction. If a gas cluster including several thousands of atoms collides with an implantation target, a high-temperature and high-pressure region is instantaneously formed in the vicinity of the collision. Thus, the region of the target is instantaneously melted and the atoms to be implanted are penetrated into the melted region. A penetrated depth of impurities is determined by a depth of the melted region, and a profile of the impurities becomes very steep. Further, in colliding with the gas cluster, since many-body collision occurs in the vicinity of a target surface to be irradiated, the above-described channeling does not occur. Further, due to the above melting process, there is an effect of collapsing a crystal structure of the target film. Thus, channeling does not occur. Furthermore, an average number of atoms contained in the cluster may be set to be several thousands or more as described above, and energy per atom may be set to be significantly lower as compared with the case of ion implantation. Such effects are described in page 146 to page 147 in ISBN 4-526-05765-7 entitled “Cluster Ion Beam-Basic and Applications” written and edited by Isao Yamada and published by Nikkan Kogyo Shimbun Ltd.

(Gas Cluster Irradiation Device)

Hereinafter, a gas cluster irradiation device configured to irradiate an ionized gas cluster will be explained.

FIG. 5 illustrates a cluster ion irradiation device in the present example embodiment. The cluster ion irradiation device includes a nozzle unit 51 configured to generate a gas cluster, an ionization electrode 52, an acceleration electrode 53, and a cluster separating unit 54.

In the nozzle unit 51, a gas cluster is generated from a compressed gas. To be specific, a gas in a high-pressure condition is supplied to the nozzle unit 51, and then, discharged from the nozzle unit 51, so that a gas cluster is generated. A gas used herein is oxygen or the like, and is in a gaseous state at room temperature.

In the ionization electrode 52, the generated gas cluster is ionized. Thus, the ionized gas cluster is generated.

Thereafter, the ionized gas cluster is accelerated by the acceleration electrode 53. Herein, the gas cluster is accelerated at a speed in inverse proportion to a square root of the number, i.e. a square root of mass, of atoms constituting the gas cluster, and is also accelerated at a speed in proportion to a square root of an ionized valence number.

Then, in the cluster separating unit 54, the gas cluster is separated according to the ionized valence number or mass of the gas cluster. To be specific, the cluster separating unit 54 applies an electric field or a magnetic field to remove monomer ions which do not become cluster.

Thereafter, an ionized gas cluster 55 supplied from the gas cluster irradiation device is irradiated to a dielectric film or the like.

### Second Example Embodiment

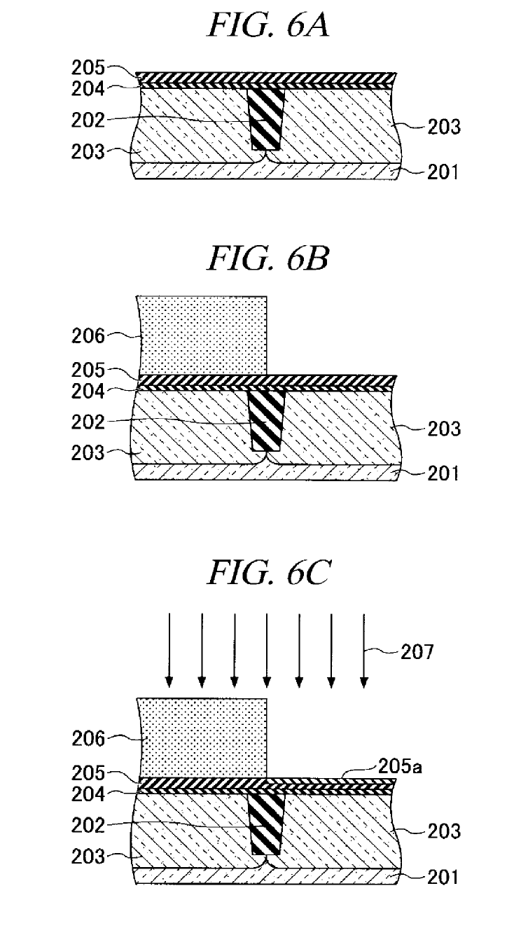

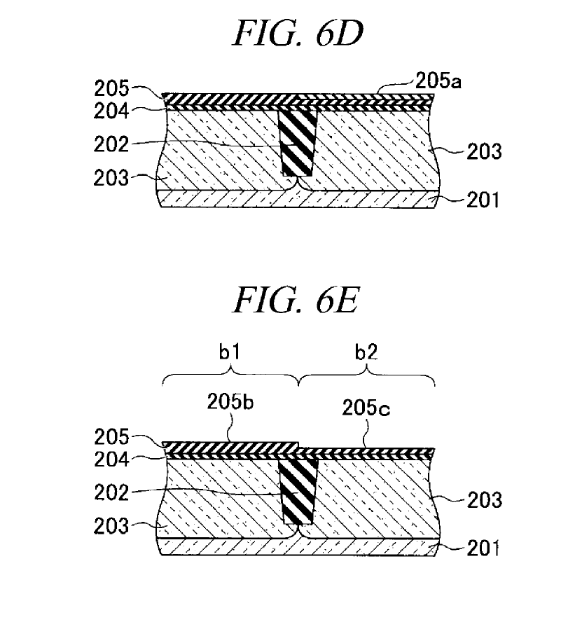

Hereinafter, a second example embodiment will be explained with reference to FIG. 6A to FIG. 6E. The present example embodiment relates to a semiconductor device manufacturing method of forming dielectric films having different thicknesses (thicknesses of high-k films) on a semiconductor substrate such as a Si substrate.

Firstly, as depicted in FIG. 6A, an element isolation region 202 and a well 203 are formed in a semiconductor substrate 201 such as a Si substrate, and an interface layer 204 using SiO₂ as a main component thereof is formed on a surface of the semiconductor substrate 201 to have a thickness of about 1 nm or less. The interface layer 204 may be formed by a chemical liquid process with a mixed liquid of H₂SO₄ and H₂O₂, a mixed liquid of NH₄OH and H₂O₂, or a liquid in which O₃ is dissolved, an oxidation process with radicals including oxygen, a thermal oxidation process in a gas including oxidizing species such as oxygen, and the like. Then, a high-k film 205 is formed on the interface layer 204. As a material of the high-k film 205, HfO₂, ZrO₂, Al₂O₃, Ta₂O₅, TiO₂, rare earth oxides and mixtures thereof, materials in which Si is added thereto, and materials in which a nitriding process is performed thereon may be used. A thickness of the high-k film 205 is set to satisfy thickness requirements of a thick portion thereof and a thin portion thereof in consideration of an amount of the high-k film 205 to be removed in the etching process. Although CVD or ALD may be performed in forming the high-k film, PVD or plasma nitriding process may be performed together depending on a kind of a material to be added.

Thereafter, as depicted in FIG. 6B, a resist pattern 206 is formed on a region where the high-k film 205 remains thick.

Then, as depicted in FIG. 6C, an ionized gas cluster 207 is irradiated. This ionized gas cluster 207 is the same as the ionized gas cluster explained in the first example embodiment, and modifies a state of a surface of a region where the ionized gas cluster is irradiated. Thus, a modified layer 205a is formed at a portion in a thickness direction at a region where the resist pattern 206 is not formed.

Thereafter, as depicted in FIG. 6D, the resist pattern 206 is removed by using a mixed liquid of H₂SO₄ and H₂O₂ or by ashing.

Then, as depicted in FIG. 6E, wet etching is carried out with dilute hydrofluoric acid. The region where the ionized gas cluster is not irradiated corresponds to the sample A depicted in FIG. 4 and is rarely etched. Meanwhile, the region where the ionized gas cluster is irradiated corresponds to the sample B depicted in FIG. 4, and a surface thereof is etched to about 1 nm to about 2 nm but rarely further etched. As such, the modified layer 205a is removed. Thus, there are formed a region b1 where a thick high-k film 205b which is not removed by the wet etching is formed and a region b2 where a thin high-k film 205c from which the modified layer 205a is removed is formed.

According to the manufacturing method of the present example embodiment, while a surface of the semiconductor substrate 201 is exposed, resist is not formed on the surface of the semiconductor substrate 201 such as a Si substrate. That is, when forming a gate insulating film later, C (carbon) or the like from the resist pattern 206 is not attached or not diffused. Therefore, it is possible to suppress an interface state from being generated at an interface between the semiconductor substrate 201 as the Si substrate and the gate insulating film and to suppress dielectric breakdown voltage of the gate insulating film from being reduced. Thus, a high-quality MISFET can be manufactured.

Further, in the conventional technology, a high-k film is used in order to suppress a leakage current, and SiO₂ is used in order to form a thickness difference. Therefore, since there is a region in which a thick SiO₂ film and the high-k film are stacked, a leakage current reduction effect is low as compared with a case where a high-k film is entirely used. However, in the present example embodiments, since only high-k film is used in order to suppress a leakage current, a thickness ratio of the high-k film in an insulating film layered structure is increased. For this reason, the leakage current reduction effect is increased, and a high-quality MISFET having a low leakage current can be manufactured.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

This International patent application claims the benefit of priority to Japanese Patent Application No. 2011-220257 filed on Oct. 4, 2011 and incorporated herein by reference in its entirety.

We claim:

1. A semiconductor device manufacturing method comprising:
forming a dielectric film on a semiconductor substrate;
forming a resist pattern on the dielectric film;
irradiating an ionized gas cluster to a region of the dielectric film where the resist pattern is not formed; and
removing a part of the region of the dielectric film in a thickness direction thereof where the ionized gas cluster is irradiated by a wet etching,
wherein the dielectric film serves as a gate insulating film, and two regions having different thicknesses of the dielectric film are formed.

2. A semiconductor device manufacturing method comprising:
forming a first dielectric film on a semiconductor substrate;
forming a second dielectric film, which is made of a material having a relative permittivity higher than a relative permittivity of a material forming the first dielectric film, on the first dielectric film;
forming a resist pattern on the second dielectric film;
irradiating an ionized gas cluster to a region of the second dielectric film where the resist pattern is not formed; and
removing a part of the region of the second dielectric film in a thickness direction thereof where the ionized gas cluster is irradiated by a wet etching,
wherein a gate insulating film is formed of the first dielectric film and the second dielectric film, and the gate insulating film has different thicknesses at the region where the ionized gas cluster is irradiated and a region where the ionized gas cluster is not irradiated.

3. The semiconductor device manufacturing method of claim 2,
wherein a material of the first dielectric film or the second dielectric film includes any one of HfO₂, ZrO₂, Al₂O₃, Ta₂O₅, and TiO₂.

4. The semiconductor device manufacturing method of claim 1,
wherein the wet etching is carried out with dilute hydrofluoric acid.

5. The semiconductor device manufacturing method of claim 2,
wherein the wet etching is carried out with dilute hydrofluoric acid.

6. The semiconductor device manufacturing method of claim 1,
wherein an average number of atoms constituting the gas cluster is about 1000 or more.

7. The semiconductor device manufacturing method of claim 2,
wherein an average number of atoms constituting the gas cluster is about 1000 or more.
